(19) United States
(12) Patent Application Publication
(10) Pub. No.: US 2010/0193850 A1
(43) Pub. Date: Aug. 5, 2010

(54) SEMICONDUCTOR MEMORY DEVICE

(75) Inventors: Yoshiaki ASAO, Kawasaki-shi (JP); Takeshi KAJIYAMA, Yokohama-shi (JP); Minoru AMANO, Sagamihara-shi (JP); Yoshikuni TATEYAMA, Hiratsuka-shi (JP); Atsushi SHIGETA, Yokkaichi-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/697,912

(22) Filed: Feb. 1, 2010

(30) Foreign Application Priority Data
Feb. 2, 2009 (JP) 2009-021653

(51) Int. Cl. H01L 29/82

(52) U.S. Cl. 257/295; 257/E29.323

(57) ABSTRACT

First and second transistors are formed on a substrate. An interlayer insulating film is formed on the first transistor. A first contact is formed in the interlayer film on a source or a drain of the first transistor. A second contact is formed in the interlayer film on the other of the source or the drain. A first interconnect is formed on the first contact. A magnetoresistive element is formed on the second contact. The magnetoresistive element is arranged in a layer having a height equal to that of the first interconnect from a substrate surface. A third contact is formed in the interlayer film on a source or a drain of the second transistor. A second interconnect is formed on the third contact. The second interconnect is arranged in a layer having a height equal to those of the first interconnect and the magnetoresistive element from the substrate surface.

### CROSS-REFERENCE TO RELATED APPLICATIONS

This application is based upon and claims the benefit of priority from prior Japanese Patent Application No. 2009-021653, filed Feb. 2, 2009, the entire contents of which are incorporated herein by reference.

### BACKGROUND OF THE INVENTION

1. Field of the Invention

The present invention relates to a semiconductor memory device, for example, a logic embedded memory in which a magnetic random access memory and a logic circuit are embedded.

2. Description of the Related Art

In recent years, a large number of memories which store information by a new principle are proposed. As one of such memories, a spin injection magnetic random access memory (MRAM) is proposed (for example, see IEDM2005 Technical Digest p. 473 to 476, “A Novel Nonvolatile Memory with Spin Torque Transfer Magnetization Switching: Spin-RAM”, Journal of Magnetism and Magnetic Materials 159 [1996] L1 to L6, “Current-driven excitation of magnetic multilayers”).

The magnetic random access memory (MRAM) stores pieces of information “1” and “0” by a magnetic tunnel junction element (MTJ). The MTJ has a structure obtained by sandwiching an insulating layer (tunnel barrier) between two magnetic layers (ferromagnetic layers). The pieces of information stored in the MTJ are determined by checking whether directions of spin of the two magnetic layers are parallel to each other or antiparallel to each other. In this case, the parallel means that the directions of spin of the two magnetic layers are equal to each other, and the antiparallel means that the directions of spin of the two magnetic layers are opposite to each other.

In general, an antiferromagnetic layer is arranged on one side of the two magnetic layers, and a magnetic layer on the side on which the antiferromagnetic layer is arranged is called a fixed layer. The antiferromagnetic layer is a member to fix the direction of spin of the magnetic layer on one side. The direction of spin of the magnetic layer, on the other side, called a recording layer is changed to rewrite the information stored in the MTJ.

When the directions of spin of the two magnetic layers become parallel to each other, a tunnel resistance of the insulating layer (tunnel barrier) sandwiched by the two magnetic layers becomes minimum. This state is a state “1”. When the directions of spin of the two magnetic layers become antiparallel to each other, the tunnel resistance of the insulating layer (tunnel barrier) sandwiched by the two magnetic layers becomes maximum. This state is a state “0”.

At present, a logic embedded MRAM in which a logic circuit and an MRAM are embedded attracts attention. In the logic portion in the logic embedded MRAM, a via hole which is not formed in a standard logic circuit structure must be inserted into a portion between a contact plug connected to a source region or a drain region and a first interconnect layer. For this reason, a process of the logic circuit in the logic embedded MRAM cannot be consistent with a process in the standard logic circuit.

In this case, conventional design resources, for example, a design library or the like cannot be diverted to a logic circuit of a logic embedded MRAM, possibly increasing design costs. More specifically, in the logic circuit in a present logic embedded MRAM, a design library registered for a standard logic circuit cannot be used, and a design library for MRAM must be newly created. As a result, the price of a chip on which the logic embedded MRAM is mounted disadvantageously becomes high.

Furthermore, at present, in the sectional structure of a logic circuit in a logic embedded MRAM, a via hole is arranged between a contact plug connected to a source region or a drain region and a first interconnect layer. For this reason, a resistance in the logic circuit increases, which is one of the causes of prevention of a high-speed operation.

### BRIEF SUMMARY OF THE INVENTION

According to a first aspect of the present invention, there is provided a semiconductor memory device comprising: a first MOS transistor formed on a semiconductor substrate; an interlayer insulating film formed on the first MOS transistor; a first contact plug formed in the interlayer insulating film on one of a source region and a drain region of the first MOS transistor; a second contact plug formed in the interlayer insulating film on the other of the source region and the drain region; a first interconnect layer formed on the first contact plug; a magnetoresistive effect element formed on the second contact plug, the magnetoresistive effect element being arranged in a layer having a height equal to that of the first interconnect layer from a semiconductor substrate surface; a second MOS transistor formed on the semiconductor substrate; a third contact plug formed in the interlayer insulating film on one of a source region and a drain region of the second MOS transistor; and a second interconnect layer formed on the third contact plug, the second interconnect layer being arranged in a layer having a height equal to those of the first interconnect layer and the magnetoresistive effect element from the semiconductor substrate surface.

According to a second aspect of the present invention, there is provided a semiconductor memory device comprising: a first MOS transistor formed on a semiconductor substrate; an interlayer insulating film formed on the first MOS transistor; a first contact plug formed in the interlayer insulating film on one of a source region and a drain region of the first MOS transistor; a second contact plug formed in the interlayer insulating film on the other of the source region and the drain region; a first interconnect layer formed on the first contact plug; a magnetoresistive effect element formed on the second contact plug, the magnetoresistive effect element being arranged in a layer having a height equal to that of the first interconnect layer from a semiconductor substrate surface; a second MOS transistor formed on the semiconductor substrate; a third contact plug formed in the interlayer insulating film on one of a source region and a drain region of the second MOS transistor; and a second interconnect layer formed on the third contact plug, a bottom surface of the second interconnect layer being arranged at a position higher than a bottom surface of the first interconnect layer from the semiconductor substrate surface.

According to a third aspect of the present invention, there is provided a semiconductor memory device comprising: a first MOS transistor formed on a semiconductor substrate; a first interlayer insulating film formed on the first MOS transistor; a first contact plug formed in the first interlayer insulating film on one of a source region and a drain region of the first MOS transistor; a second contact plug formed in the first interlayer insulating film on the other of the source region and the drain region; a first interconnect layer formed on the first contact plug; a second interconnect layer formed on the second contact plug, the second interconnect layer being arranged in a layer having a height equal to that of the first interconnect layer from a semiconductor substrate surface; a second interlayer insulating film formed on the first interlayer insulating film; a third interconnect layer formed in the second interlayer insulating film on the first interconnect layer; a magnetoresistive effect element formed in the second interlayer insulating film on the second interconnect layer; a second MOS transistor formed on the semiconductor substrate; a third contact plug formed in the first interlayer insulating film on one of a source region and a drain region of the second MOS transistor; and a fourth interconnect layer formed on the third contact plug, the fourth interconnect layer being arranged in a layer having a height equal to those of the first interconnect layer and the second interconnect layer from the semiconductor substrate surface.

### BRIEF DESCRIPTION OF THE SEVERAL VIEWS OF THE DRAWING

FIG. 1 is a sectional view showing a structure of a semiconductor memory device according to a first embodiment of the present invention;

FIG. 2 is a sectional view of a first step showing a method of manufacturing the semiconductor memory device according to the first embodiment;

FIG. 3 is a sectional view of a second step showing the method of manufacturing the semiconductor memory device according to the first embodiment;

FIG. 4 is a sectional view of a third step showing the method of manufacturing the semiconductor memory device according to the first embodiment;

FIG. 5 is a sectional view of a fourth step showing the method of manufacturing the semiconductor memory device according to the first embodiment;

FIG. 6 is a sectional view of a fifth step showing the method of manufacturing the semiconductor memory device according to the first embodiment;

FIG. 7 is a sectional view showing a structure of a semiconductor memory device according to a second embodiment of the present invention;

FIG. 8 is a sectional view of a first step showing a method of manufacturing the semiconductor memory device according to the second embodiment;

FIG. 9 is a sectional view of a second step showing the method of manufacturing the semiconductor memory device according to the second embodiment;

FIG. 10 is a sectional view of a third step showing the method of manufacturing the semiconductor memory device according to the second embodiment;

FIG. 11 is a sectional view showing a structure of a semiconductor memory device according to a third embodiment of the present invention;

FIG. 12 is a sectional view of a first step showing a method of manufacturing the semiconductor memory device according to the third embodiment;

FIG. 13 is a sectional view of a second step showing the method of manufacturing the semiconductor memory device according to the third embodiment;

FIG. 14 is a sectional view of a third step showing the method of manufacturing the semiconductor memory device according to the third embodiment;

FIG. 15 is a sectional view of a fourth step showing the method of manufacturing the semiconductor memory device according to the third embodiment;

FIG. 16 is a sectional view of a fifth step showing the method of manufacturing the semiconductor memory device according to the third embodiment;

FIG. 17 is a sectional view showing a structure of a semiconductor memory device according to a fourth embodiment of the present invention;

FIG. 18 is a sectional view of a first step showing a method of manufacturing the semiconductor memory device according to the fourth embodiment;

FIG. 19 is a sectional view of a second step showing the method of manufacturing the semiconductor memory device according to the fourth embodiment;

FIG. 20 is a sectional view of a third step showing the method of manufacturing the semiconductor memory device according to the third embodiment;

FIG. 21 is a sectional view of a fourth step showing the method of manufacturing the semiconductor memory device according to the third embodiment;

FIG. 22 is a sectional view showing a structure of a semiconductor memory device according to a fifth embodiment of the present invention;

FIG. 23 is a sectional view of a first step showing a method of manufacturing the semiconductor memory device according to the fifth embodiment;

FIG. 24 is a sectional view of a second step showing the method of manufacturing the semiconductor memory device according to the fifth embodiment;

FIG. 25 is a sectional view of a third step showing the method of manufacturing the semiconductor memory device according to the fifth embodiment;

FIG. 26 is a sectional view of a fourth step showing the method of manufacturing the semiconductor memory device according to the fifth embodiment;

FIG. 27 is a sectional view of a fifth step showing the method of manufacturing the semiconductor memory device according to the fifth embodiment; and

FIG. 28 is a sectional view showing a structure of an MTJ element included in the semiconductor memory device according to the embodiments.

### DETAILED DESCRIPTION OF THE INVENTION

Semiconductor memory devices according to embodiments of the present invention will be described below with reference to the accompanying drawings. In the embodiments, as the semiconductor memory devices, logic embedded MRAMs on which MRAMs and logic circuits are embedded will be exemplified. In the explanations, common reference numbers in all the drawings denote common parts, respectively.

### First Embodiment

A semiconductor memory device according to a first embodiment of the present invention will be described below.

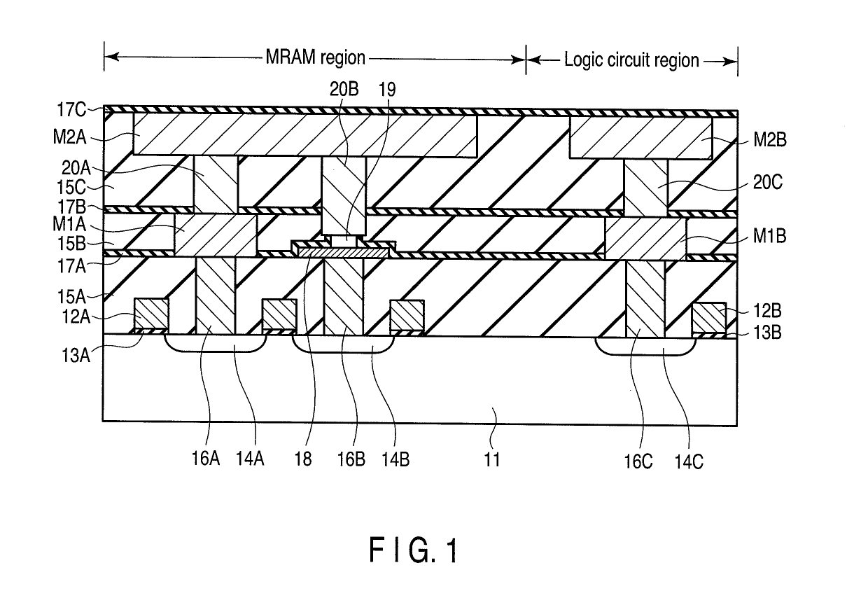

FIG. 1 is a sectional view showing a structure of the semiconductor memory device according to the first embodiment. As shown in FIG. 1, the semiconductor memory device has an MRAM region in which an MRAM is formed and a logic circuit region in which a logic circuit is formed.

A structure of the MRAM region is as follows. On a semiconductor substrate 11, a MOS field effect transistor (MOS transistor) having a gate electrode 12A, a gate insulating film 13A, and source or drain regions (diffusion layers) 14A and 14B is formed.

An interlayer insulating film 15A is formed on the semiconductor substrate 11 on which the MOS transistor is formed. In interlayer insulating film 15A on diffusion layer 14A of the MOS transistor, a contact plug 16A is formed to be in contact with diffusion layer 14A. Furthermore, in interlayer insulating film 15A on diffusion layer 14B, a contact plug 16B is formed to be in contact with diffusion layer 14B.

A silicon nitride film 17A is formed on interlayer insulating film 15A, and an interlayer insulating film 15B is formed on silicon nitride film 17A. In interlayer insulating film 15B on contact plug 16A, a first interconnect layer M1A is formed to be in contact with contact plug 16A. On contact plug 16B, a lower electrode 18 is formed to be in contact with contact plug 16B. Furthermore, on the lower electrode 18, an MTJ element 19 serving as a magnetoresistive effect element is formed.

A silicon nitride film 17B is formed on interlayer insulating film 15B, and an interlayer insulating film 15C is formed on silicon nitride film 17B. In interlayer insulating film 15C on the first interconnect layer M1A, a contact plug 20A is formed to be in contact with the first interconnect layer M1A. In interlayer insulating films 15B and 15C on the MTJ element 19, a contact plug 20B is formed to be in contact with the MTJ element 19.

In interlayer insulating film 15C on contact plugs 20A and 20B, a second interconnect layer M2A is formed to be in contact with contact plugs 20A and 20B. Furthermore, on the second interconnect layer M2A and interlayer insulating film 15C, a silicon nitride film 17C is formed.

A structure of the logic circuit region is as follows. On the semiconductor substrate 11, a MOS transistor having gate electrode 12A, gate insulating film 13B, and diffusion layer 14C is formed. On the semiconductor substrate 11 on which the MOS transistor is formed, interlayer insulating film 15A is formed. In interlayer insulating film 15A on diffusion layer 14C of the MOS transistor, contact plug 16C is formed to be in contact with diffusion layer 14C.

Silicon nitride film 17A is formed on interlayer insulating film 15A, and interlayer insulating film 15B is formed on silicon nitride film 17A. In interlayer insulating film 15B on a contact plug 16C, a first interconnect layer M1B is formed to be in contact with contact plug 16C.

Silicon nitride film 17B is formed on interlayer insulating film 15B, and interlayer insulating film 15C is formed on silicon nitride film 17B. In interlayer insulating film 15C on the first interconnect layer M1B, a contact plug 20C is formed to be in contact with the first interconnect layer M1B. In interlayer insulating film 15C on contact plug 20C, a second interconnect layer M2B is formed to be in contact with contact plug 20C. Furthermore, on the second interconnect layer M2B and interlayer insulating film 15C, silicon nitride film 17C is formed.

A method of manufacturing a semiconductor memory device according to the first embodiment will be described below.

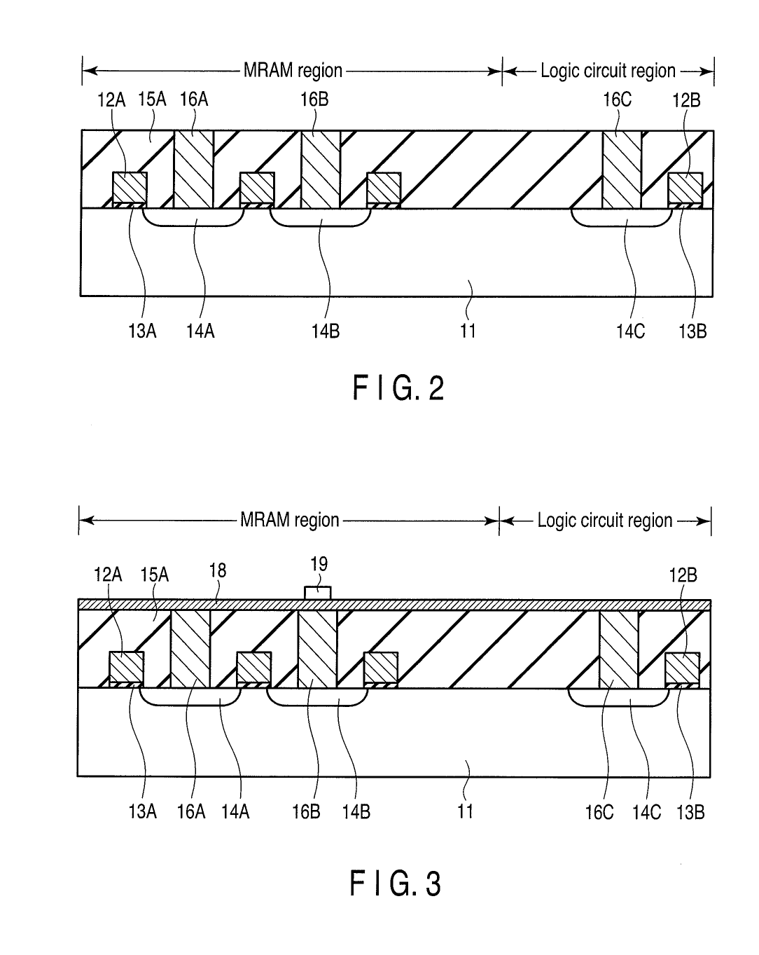

FIGS. 2 to 6 are sectional views showing the method of manufacturing a semiconductor memory device according to the first embodiment.

As shown in the drawings, the semiconductor memory device has an MRAM region in which an MRAM is formed and a logic circuit region in which a logic circuit is formed.

As shown in FIG. 2, in the MRAM region and the logic circuit region, a MOS transistor is formed on the semiconductor substrate 11. More specifically, gate insulating films 13A and 13B are formed on the semiconductor substrate 11, and gate electrodes 12A and 12B are formed on gate insulating films 13A and 13B, respectively. Furthermore, source and drain regions (diffusion layers) 14A, 14B, and 14C are formed on the semiconductor substrate 11 on both the sides of gate electrodes 12A and 12B. Subsequently, an interlayer insulating film (for example, a silicon oxide film) 15A is formed on the semiconductor substrate 11 on which a MOSFET is formed. A surface of interlayer insulating film 15A is flattened by chemical mechanical polishing (CMP).

A hole for contact plug is formed in interlayer insulating film 15A by a lithography method and reactive ion etching (RIE). Subsequently, tungsten (W) is formed on interlayer insulating film 15A to bury the hole for contact plug with tungsten. Excessive tungsten on interlayer insulating film 15A is polished by CMP to leave the tungsten in the hole for contact plug. In this manner, contact plugs 16A, 16B, and 16C are formed on diffusion layers 14A, 14B, and 14C, respectively.

As shown in FIG. 3, on interlayer insulating film 15A in which the contact plugs are formed, a conductive film (for example, Ta) 18 serving as a lower electrode is formed. Subsequently, a film serving as an MTJ element is formed on the conductive film 18. The film serving as the MTJ element is patterned by a lithography method and RIE to form the MTJ element 19 on the conductive film 18 on contact plug 16B.

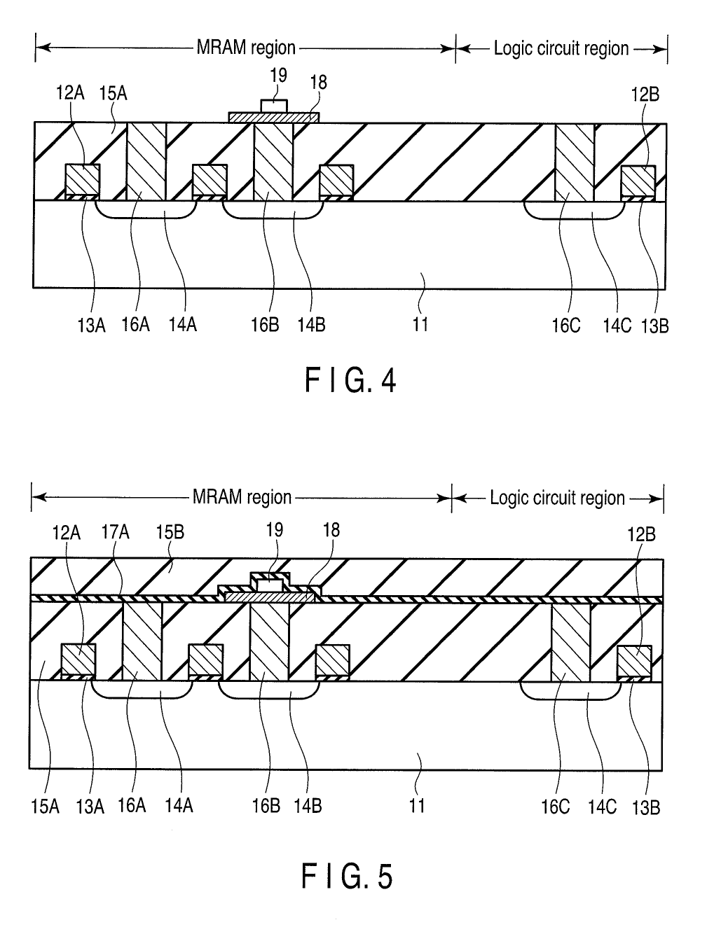

Subsequently, as shown in FIG. 4, the conductive film 18 serving as the lower electrode is patterned by a lithography method and RIE to form the lower electrode 18 under the MTJ element 19.

As shown in FIG. 5, silicon nitride film 17A is deposited on the structure shown in FIG. 4, and interlayer insulating film (for example, a silicon oxide film) 15B is deposited on silicon nitride film 17A. A surface of interlayer insulating film 15B is flattened by CMP.

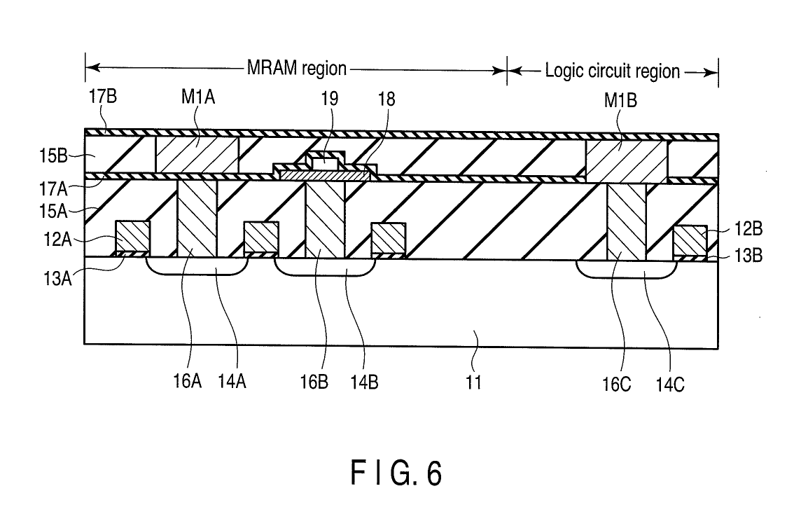

An interconnect trench to arrange the first interconnect layer is formed in interlayer insulating film 15B and silicon nitride film 17A on contact plugs 16A and 16C by a lithography method and RIE. Subsequently, a barrier metal and a Cu seed layer are formed in the interconnect trench by a sputtering method. Furthermore, Cu plating is formed on the Cu seed layer. Excessive Cu on interlayer insulating film 15B is polished by CMP, as shown in FIG. 6, and the first interconnect layers M1A and M1B each having a damascene structure are formed in interlayer insulating film 15B. Furthermore, silicon nitride film 17B is deposited on the first interconnect layers M1A and M1B and interlayer insulating film 15B.

Interlayer insulating film 15C is formed on the structure shown in FIG. 6. Subsequently, holes for contact plug are formed in interlayer insulating film 15C on the first interconnect layers M1A and M1B and in interlayer insulating films 15B and 15C on the MTJ element 19, respectively, by a lithography method and RIE. Furthermore, an interconnect trench to arrange a second interconnect layer is formed in interlayer insulating film 15C on the hole for contact plug by a lithography method and RIE. A barrier metal and a Cu seed layer are formed in the holes for contact plug and the interconnect trench by a sputtering method. Furthermore, Cu plating is formed on the Cu seed layer. Excessive Cu on interlayer insulating film 15C is polished by CMP and, as shown in FIG. 1, contact plugs 20A, 20B, and 20C and the second interconnect layers M2A and M2B having a dual damascene structure are formed. Furthermore, silicon nitride film 17C is deposited on the second interconnect layers M2A and M2B and interlayer insulating film 15C. As described above, a semiconductor memory device in which an MRAM and a logic circuit are embedded is manufactured.

In a sectional structure of a logic circuit region in the logic embedded MRAM, since a via hole is arranged between a contact plug connected to the diffusion layer and the first interconnect layer, a resistance in the logic circuit increases, which is one of the causes of prevention of a high-speed operation. However, according to the first embodiment, in the logic circuit region in the logic embedded MRAM, no via hole is arranged between contact plug 16C and the first interconnect layer M1B, and a first interconnect layer is directly formed on the contact plug. In this manner, since the resistance in the logic circuit can be reduced, the high-speed operation of the logic embedded MRAM becomes possible.

Furthermore, after the MTJ element is formed in the MRAM region, an interlayer insulating film is deposited, and the first interconnect layers M1A and M1B each having a damascene structure are formed at the same level as that of the MTJ element (in a layer having a height almost equal to that of the MTJ element from a substrate surface) to make the structure of the logic circuit almost equal to the structure of the standard logic circuit. In this manner, a process of the logic circuit in the logic embedded MRAM is consistent with a process of a standard logic circuit.

### Second Embodiment

A semiconductor memory device according to a second embodiment of the present invention will be described below. The same reference numbers as in the configuration in the first embodiment denote the same parts in the second embodiment.

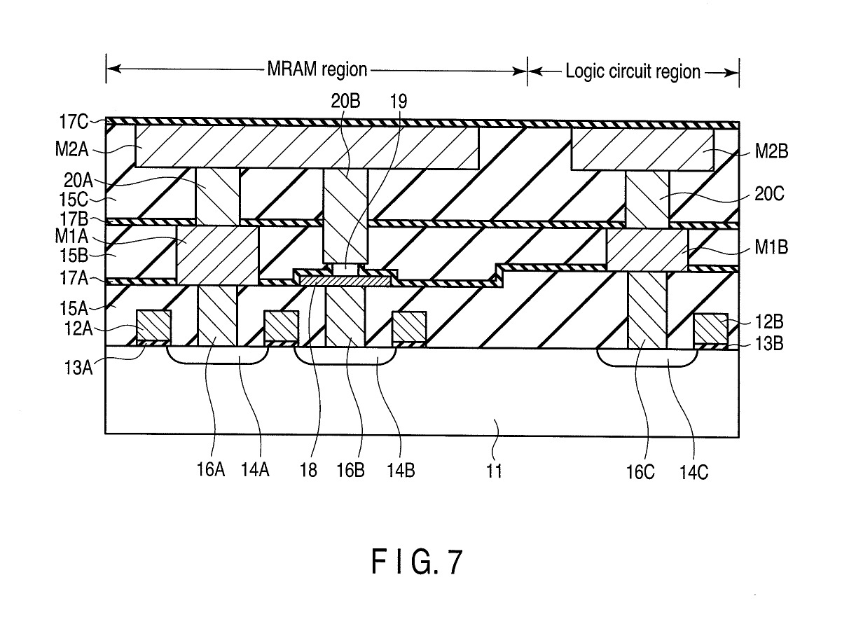

FIG. 7 is a sectional view showing a structure of a semiconductor memory device according to the second embodiment. In the first embodiment, it is observed that the MTJ element 19 tends to be excessively etched by a smoothing process (polishing step by CMP) for the first interconnect layers M1A and M1B. More specifically, in the polishing step of Cu by CMP performed after Cu plating is formed, a surface of the MTJ element 19 may be etched.

The second embodiment has a structure which solves this problem. A bottom surface of the lower electrode 18 formed under the MTJ element 19 is formed at a position lower than a bottom surface of the first interconnect layer M1B in a logic circuit region. In this manner, a distance between an upper surface of the MTJ element 19 and upper surfaces of the first interconnect layers M1A and M1B is longer than that in the first embodiment. As a manufacturing method, after contact plugs 16A, 16B, and 16C are formed, an MRAM region is etched by lithography or the like in a predetermined depth. Thereafter, the MTJ element 19 may be formed, and interlayer insulating film 15B may be deposited.

A method of manufacturing a semiconductor memory device according to the second embodiment will be described below.

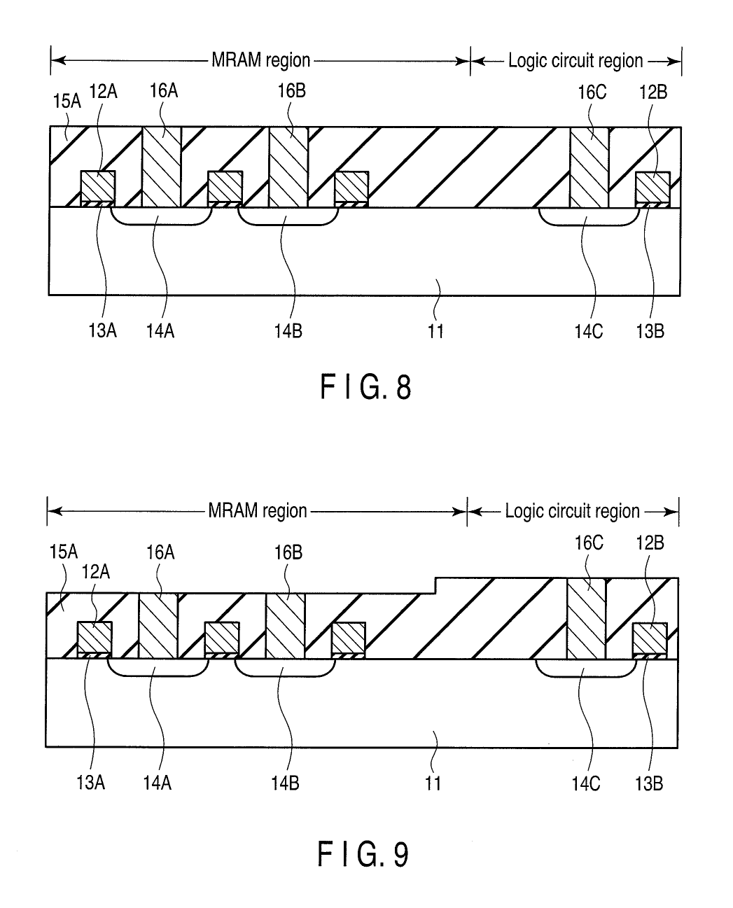

FIGS. 8 to 10 are sectional views showing the method of manufacturing a semiconductor memory device according to the second embodiment.

As shown in FIG. 8, in an MRAM region and a logic circuit region, a MOS transistor is formed on the semiconductor substrate 11. Subsequently, interlayer insulating film 15A is formed on the semiconductor substrate 11 on which a MOSFET is formed. Furthermore, on diffusion layers 14A, 14B, and 14C, contact plugs 16A, 16B, and 16C are formed, respectively. The above steps are the same as those shown in FIG. 2.

Surfaces of interlayer insulating film 15A and contact plugs 16A and 16B in the MRAM region are etched by a lithography method and RIE and, as shown in FIG. 9, surfaces of interlayer insulating film 15A and contact plugs 16A and 16B in the MRAM region are made, for example, about 100 nm lower than the surface of interlayer insulating film 15A in the logic circuit region.

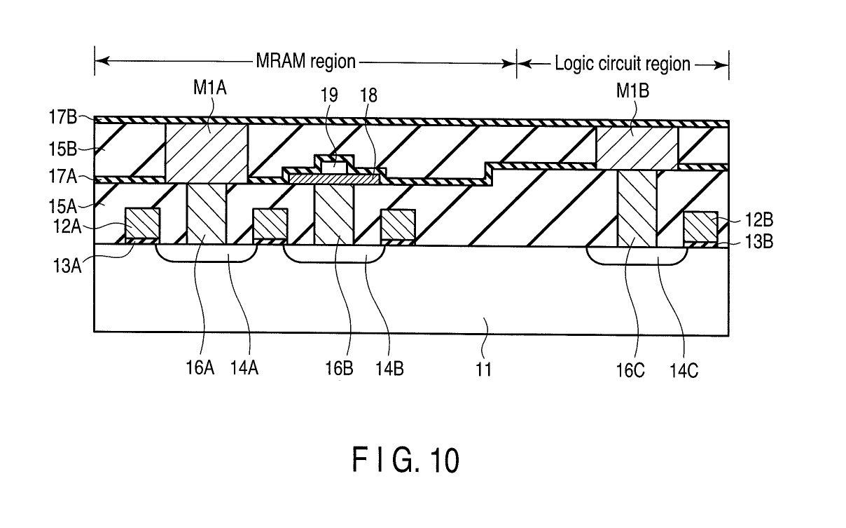

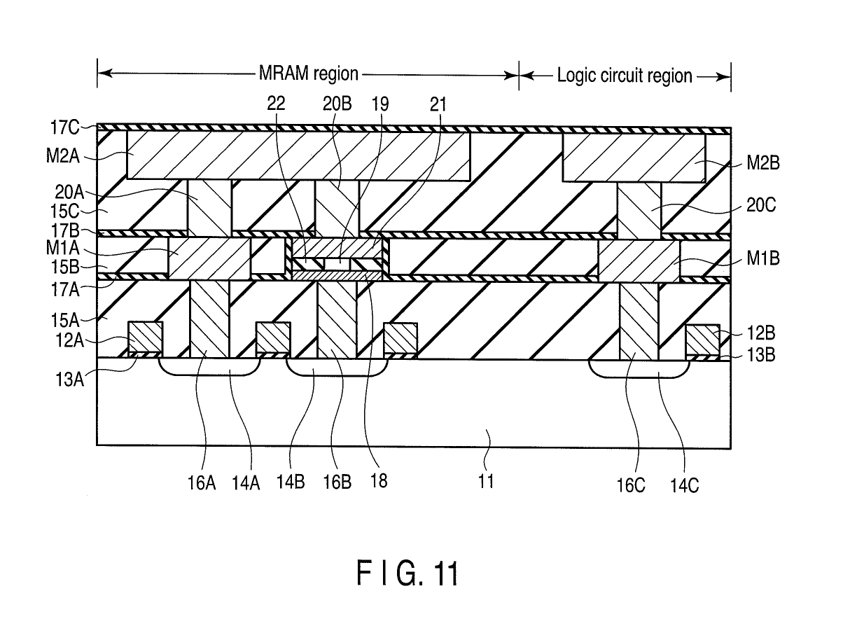

By the same steps as those in the first embodiment, a structure shown in FIG. 10 is formed. More specifically, the lower electrode 18 and the MTJ element 19 are formed on contact plug 16B. Thereafter, silicon nitride film 17A is deposited on contact plugs 16A and 16C, the MTJ element 19, and interlayer insulating film 15A. Furthermore, interlayer insulating film (for example, a silicon oxide film) 15B is deposited on silicon nitride film 17A. Thereafter, the first interconnect layers M1A and M1B each having a damascene structure are formed in interlayer insulating film 15B. Furthermore, silicon nitride film 17B is deposited on the first interconnect layers M1A and M1B and interlayer insulating film 15B.

Thereafter, by the same steps as those in the first embodiment, a structure as shown in FIG. 7 is formed. More specifically, interlayer insulating film 15C is formed, and contact plugs 20A, 20B, and 20C and the second interconnect layers M2A and M2B are formed. Furthermore, on the first interconnect layers M2A and M2B and interlayer insulating film 15C, silicon nitride film 17C is deposited. In this manner, a semiconductor memory device in which an MRAM and a logic circuit are embedded is manufactured.

In the second embodiment, a bottom surface of the lower electrode 18 formed under the MTJ element 19 is formed at a position lower than a bottom surface of the first interconnect layer M1B in the logic circuit region, and a distance between an upper surface of the MTJ element 19 and upper surfaces of the first interconnect layers M1A and M1B is longer than that in the first embodiment. In this manner, the MTJ element 19 can be suppressed from being etched in a Cu polishing step performed by CMP. The other configurations and effects are the same as those in the first embodiment.

### Third Embodiment

A semiconductor memory device according to a third embodiment of the present invention will be described below. The same reference numbers as in the configuration in the first embodiment denote the same parts in the third embodiment.

In the first embodiment, since contact plugs to the first interconnect layers M1A and M1B and a contact plug to the MTJ element 19 have different depths, the number of steps to form holes for contact plug increases. In order to suppress this increase, an electrode (intermediate plug) is formed on the MTJ element 19 to make depths of a contact plug to the first interconnect layer and a contact plug to the MTJ element equal to each other.

FIG. 11 is a sectional view showing a structure of the semiconductor memory device according to the third embodiment.

As shown in the drawing, an intermediate plug (electrode) 21 is formed between the MTJ element 19 and contact plug 20B.

In this manner, upper surfaces of the first interconnect layers M1A and M1B and an upper surface of the intermediate plug 21 become equal to each other in height. As a result, the depths of contact plugs 20A and 20C connected to the first interconnect layer and a depth of contact plug 20B connected to the MTJ element can be made equal to each other, and thus the number of steps to form holes for the contact plugs can be prevented from increasing.

A method of manufacturing a semiconductor memory device according to the third embodiment will be described below.

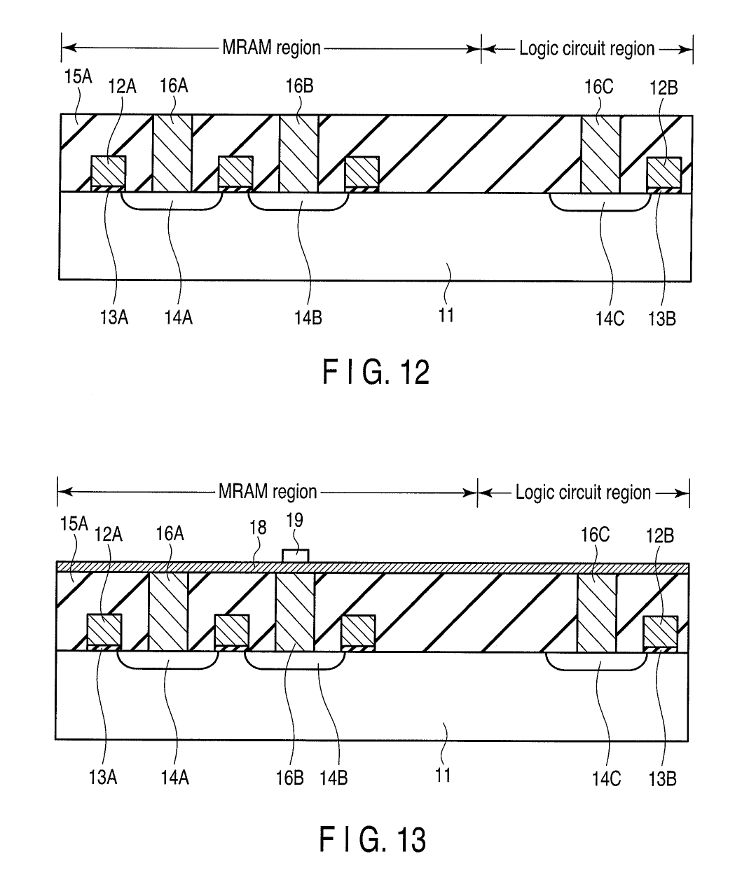

FIGS. 12 to 16 are sectional views showing the method of manufacturing a semiconductor memory device according to the third embodiment.

As shown in FIG. 12, in an MRAM region and a logic circuit region, a MOS transistor is formed on the semiconductor substrate 11. Subsequently, interlayer insulating film 15A is formed on the semiconductor substrate 11 on which a MOSFET is formed. Furthermore, on diffusion layers 14A, 14B, and 14C, contact plugs 16A, 16B, and 16C are formed, respectively. The above steps are the same as those shown in FIG. 2.

As shown in FIG. 13, on interlayer insulating film 15A on which a contact plug is formed, the conductive film (for example, Ta) 18 serving as a lower electrode is formed. Subsequently, a film serving as an MTJ element is formed on the conductive film 18. The film serving as the MTJ element is patterned by a lithography method and RIE to form the MTJ element 19 on the conductive film 18 on contact plug 16B.

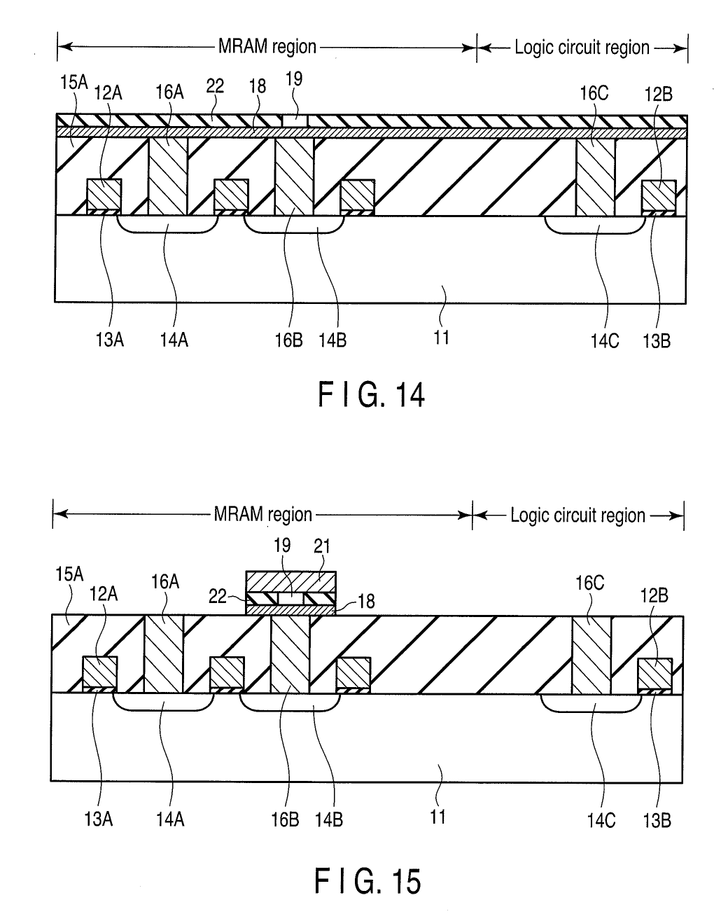

As shown in FIG. 14, an interlayer insulating film 22 is deposited on the structure shown in FIG. 13. Subsequently, a surface of the interlayer insulating film 22 is flattened by CMP to expose the surface of the MTJ element 19. Thereafter, a film serving as an intermediate plug is deposited on the interlayer insulating film 22. The film serving as the intermediate plug, the interlayer insulating film 22, and the conductive film 18 are patterned by a lithography method and RIE, as shown in FIG. 15, to form the intermediate plug 21 on the MTJ element 19 and to form the lower electrode 18 on contact plug 16B.

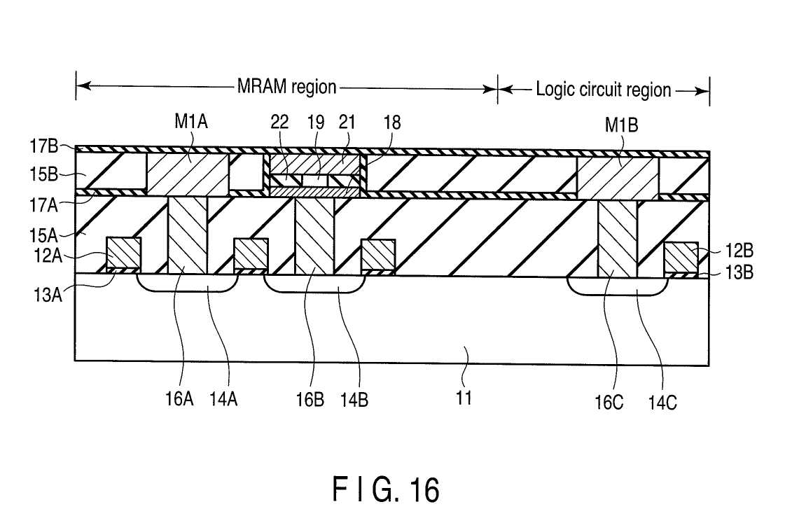

As shown in FIG. 16, silicon nitride film 17A is deposited on the structure shown in FIG. 15, and interlayer insulating film (for example, a silicon oxide film) 15B is deposited on silicon nitride film 17A. Thereafter, a surface of interlayer insulating film 15B is flattened by CMP.

An interconnect trench to arrange a first interconnect layer is formed in interlayer insulating film 15B and silicon nitride film 17A on contact plugs 16A and 16C by a lithography method and RIE. Subsequently, a barrier metal and a Cu seed layer are formed in the interconnect trench by a sputtering method. Furthermore, Cu plating is formed on the Cu seed layer. Excessive Cu on interlayer insulating film 15B is polished by CMP, as shown in FIG. 16, to form the first interconnect layers M1A and M1B each having a damascene structure in interlayer insulating film 15B. Furthermore, silicon nitride film 17B is deposited on the first interconnect layers M1A and M1B, the intermediate plug 21, and interlayer insulating film 15B.

Interlayer insulating film 15C is formed on the structure shown in FIG. 16. Subsequently, holes for contact plug are formed in interlayer insulating film 15C on the first interconnect layers M1A and M1B and the intermediate plug 21 by a lithography method and RIE. Furthermore, an interconnect trench to arrange a second interconnect layer is formed in interlayer insulating film 15C on the hole for contact plug by a lithography method and RIE. A barrier metal and a Cu seed layer are formed in the holes for contact plug and the interconnect trench by a sputtering method. Furthermore, Cu plating is formed on the Cu seed layer. Excessive Cu on interlayer insulating film 15C is polished by CMP, as shown in FIG. 11, to form contact plugs 20A, 20B, and 20C each having a dual damascene structure and the second interconnect layers M2A and M2B. Furthermore, silicon nitride film 17C is deposited on the second interconnect layers M2A and M2B and interlayer insulating film 15C. In this manner, a semiconductor memory device on which an MRAM and a logic circuit are embedded is manufactured.

In the third embodiment, since a depth of the contact plug connected to the first interconnect layer and a depth of a contact plug connected to the MTJ element are equal to each other, the number of steps to form holes for contact plug can be reduced. The other configurations and effects are the same as those in the first embodiment.

### Fourth Embodiment

A semiconductor memory device according to a fourth embodiment of the present invention will be described below. The same reference numbers as in the configuration in the first embodiment denote the same parts in the fourth embodiment.

In the fourth embodiment, the MTJ element 19 is formed at the same level (in a layer having a height almost equal to that of contact plug 20A from a semiconductor substrate surface) as that of contact plug 20A in an MRAM region to make a via hole under a first interconnect layer in a logic circuit region unnecessary.

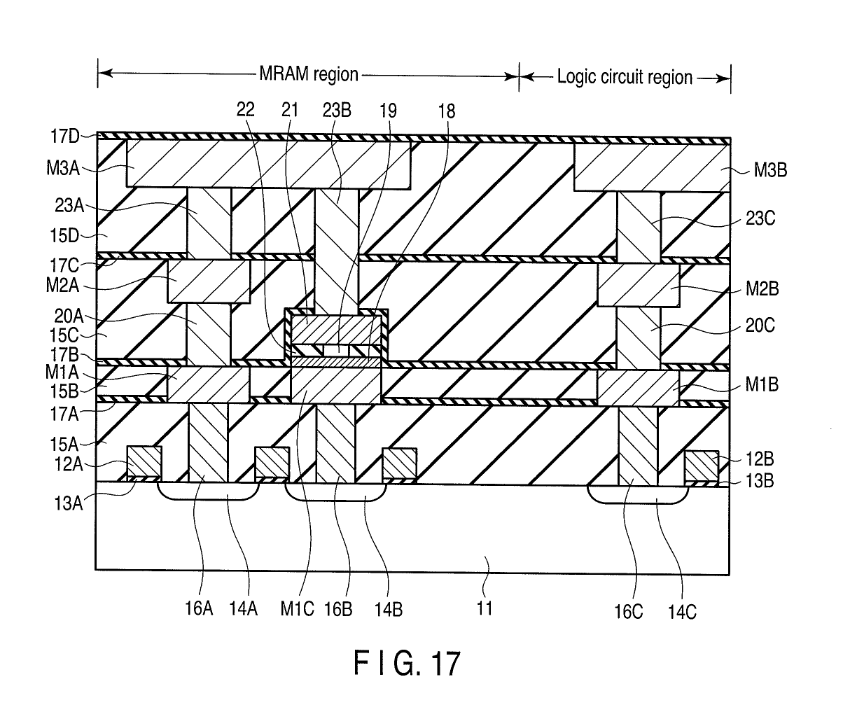

FIG. 17 is a sectional view showing a structure of the semiconductor memory device according to the fourth embodiment.

A structure of the MRAM region is as follows. As in the first embodiment, a MOS transistor is formed on the semiconductor substrate 11. Interlayer insulating film 15A is formed on the semiconductor substrate 11. On diffusion layer 14A of the MOS transistor, contact plug 16A is formed to be in contact with diffusion layer 14A. Furthermore, on diffusion layer 14B, contact plug 16B is formed to be in contact with diffusion layer 14B.

Silicon nitride film 17A is formed on interlayer insulating film 15A, and interlayer insulating film 15B is formed on silicon nitride film 17A. In interlayer insulating film 15B on contact plug 16A, the first interconnect layer M1A is formed to be in contact with contact plug 16A. On contact plug 16B, a first interconnect layer M1C is formed to be in contact with contact plug 16B.

The lower electrode 18 is formed on the first interconnect layer M1C, and the MTJ element 19 is formed on the lower electrode 18. The intermediate plug 21 is formed on the MTJ element 19. Furthermore, the interlayer insulating film 22 is formed between the lower electrode 18 and the intermediate plug 21.

Silicon nitride film 17B is formed on the first interconnect layer M1A, the intermediate plug 21, and interlayer insulating film 15B, and interlayer insulating film 15C is formed on silicon nitride film 17B.

In interlayer insulating film 15C on the first interconnect layer M1A, contact plug 20A is formed to be in contact with the first interconnect layer M1A. In interlayer insulating film 15C on contact plug 20A, the second interconnect layer M2A is formed to be in contact with contact plug 20A. Silicon nitride film 17C is formed on the second interconnect layer M2A and interlayer insulating film 15C. Furthermore, an interlayer insulating film 15D is formed on silicon nitride film 17C.

In interlayer insulating film 15D on the second interconnect layer M2A, a contact plug 23A is formed to be in contact with the second interconnect layer M2A. In interlayer insulating films 15C and 15D on the intermediate plug 21, a contact plug 23B is formed to be in contact with the intermediate plug 21. In interlayer insulating film 15D on contact plugs 23A and 23B, a third interconnect layer M3A is formed to be in contact with contact plugs 23A and 23B. Furthermore, a silicon nitride film 17D is formed on the third interconnect layer M3A and interlayer insulating film 15D.

A structure of a logic circuit region is as follows. As in the first embodiment, a MOS transistor is formed on the semiconductor substrate 11. Interlayer insulating film 15A is formed on the semiconductor substrate 11. In interlayer insulating film 15A on diffusion layer 14C of the MOS transistor, contact plug 16C is formed to be in contact with diffusion layer 14C.

Silicon nitride film 17A is formed on interlayer insulating film 15A, and interlayer insulating film 15B is formed on silicon nitride film 17A. In interlayer insulating film 15B on contact plug 16C, the first interconnect layer M1B is formed to be in contact with contact plug 16C.

Silicon nitride film 17B is formed on interlayer insulating film 15B and the first interconnect layer M1B, and interlayer insulating film 15C is formed on silicon nitride film 17B. In interlayer insulating film 15C on the first interconnect layer M1B, contact plug 20C is formed to be in contact with the first interconnect layer M1B. In interlayer insulating film 15C on contact plug 20C, the second interconnect layer M2B is formed to be in contact with contact plug 20C. Silicon nitride film 17C is formed on the second interconnect layer M2B and interlayer insulating film 15C. Furthermore, interlayer insulating film 15D is formed on silicon nitride film 17C.

In interlayer insulating film 15D on the second interconnect layer M2B, a contact plug 23C is formed to be in contact with the second interconnect layer M2B. In interlayer insulating film 15D on contact plug 23C, a third interconnect layer M3B is formed to be in contact with contact plug 23C. Furthermore, silicon nitride film 17D is formed on the third interconnect layer M3B and interlayer insulating film 15D.

A method of manufacturing a semiconductor memory device according to the fourth embodiment will be described below.

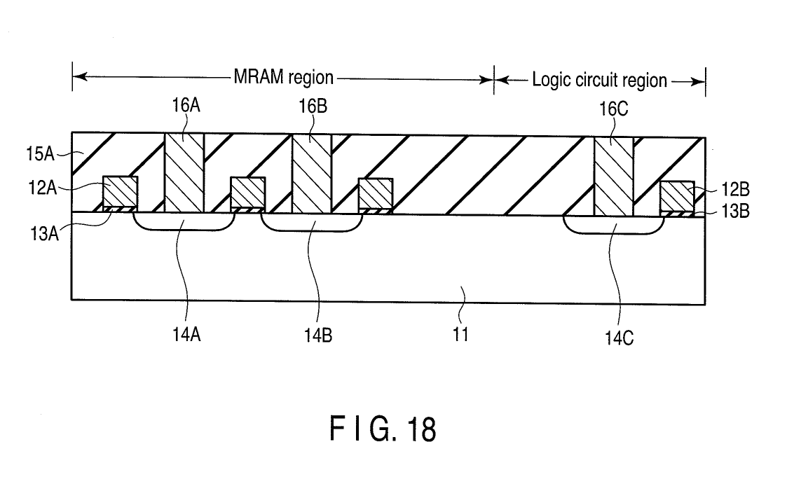

FIGS. 18 to 21 are sectional views showing the method of manufacturing a semiconductor memory device according to the fourth embodiment.

As shown in FIG. 18, in an MRAM region and a logic circuit region, a MOS transistor is formed on the semiconductor substrate 11. Subsequently, interlayer insulating film 15A is formed on the semiconductor substrate 11 on which a MOSFET is formed. Furthermore, on diffusion layers 14A, 14B, and 14C, contact plugs 16A, 16B, and 16C are formed, respectively. The above steps are the same as those shown in FIG. 2.

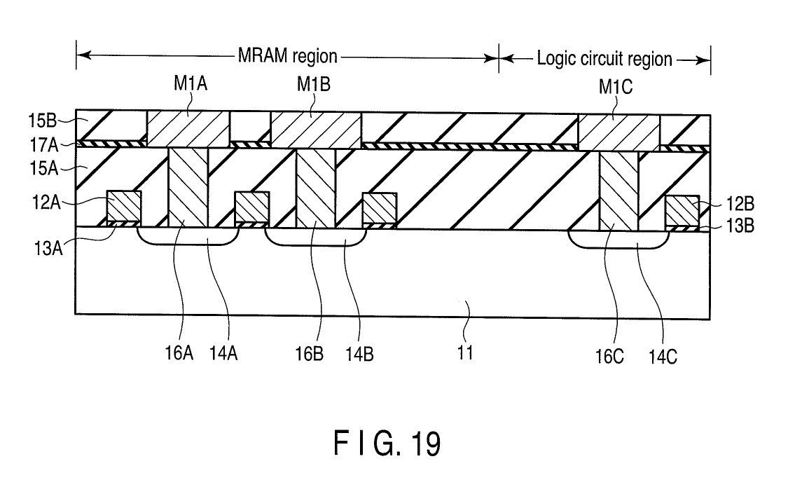

As shown in FIG. 19, silicon nitride film 17A is deposited on the structure shown in FIG. 18, and interlayer insulating film 15B is deposited on silicon nitride film 17A. Thereafter, a surface of interlayer insulating film 15B is flattened by CMP.

In interlayer insulating film 15B and silicon nitride film 17A on contact plugs 16A, 16B, and 16C, an interconnect trench to arrange a first interconnect layer is formed by a lithography method and RIE. Subsequently, a barrier metal and a Cu seed layer are formed in the interconnect trench by a sputtering method. Furthermore, Cu plating is formed on the Cu seed layer. Excessive Cu on interlayer insulating film 15B is polished by CMP and, as shown in FIG. 19, the first interconnect layers M1A, M1B, and M1C each having a damascene structure are formed in interlayer insulating film 15B.

On interlayer insulating film 15B in which the contact plug is formed, the conductive film 18 serving as a lower electrode is formed. Subsequently, a film serving as an MTJ element is formed on the conductive film 18. The film serving as the MTJ element is patterned by a lithography method and RIE to form the MTJ element 19 on the conductive film 18 on contact plug 16B.

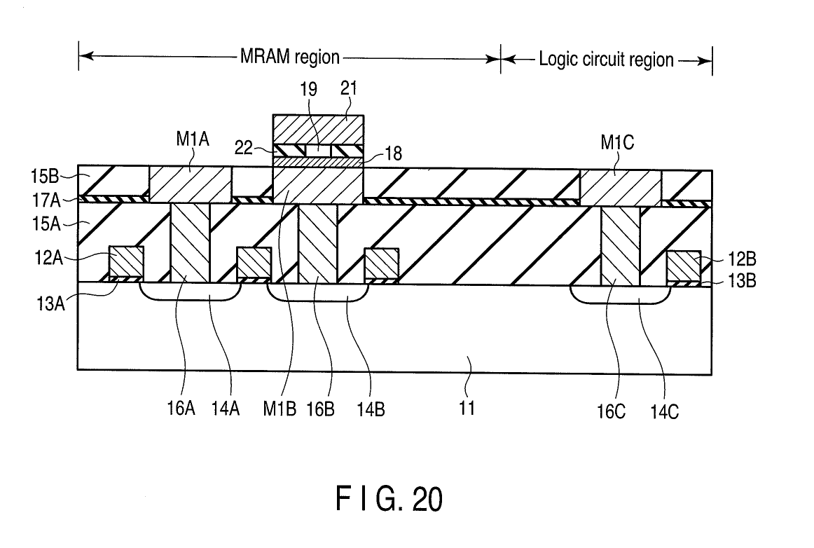

The interlayer insulating film 22 is deposited on the conductive film 18 and the MTJ element 19. Subsequently, a surface of the interlayer insulating film 22 is flattened by CMP to expose a surface of the MTJ element 19. Thereafter, a film serving as an intermediate plug is formed on the interlayer insulating film 22. The film serving as the intermediate plug, the interlayer insulating film 22, and the conductive film 18 are patterned by a lithography method and RIE, whereby, as shown in FIG. 20, the intermediate plug 21 is formed on the MTJ element 19, and a lower electrode 18 is formed on the first interconnect layer M1B.

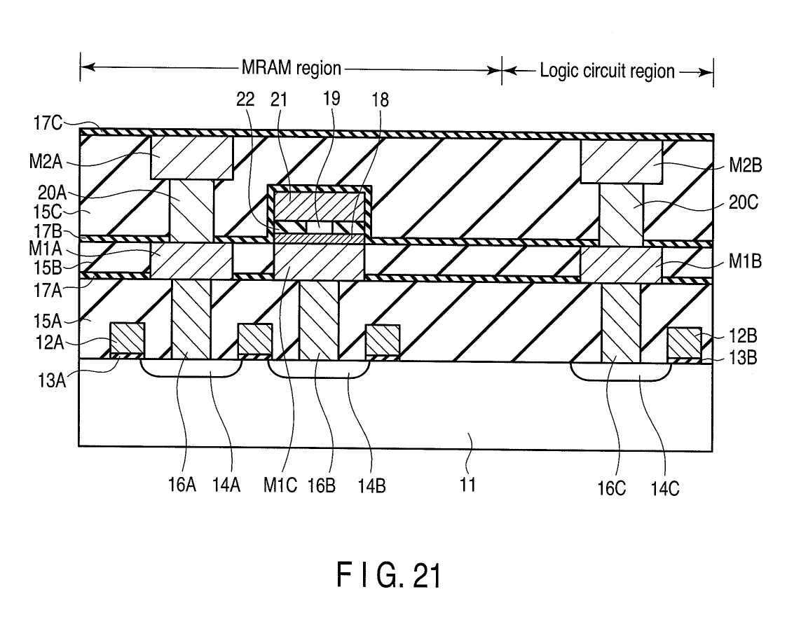

As shown in FIG. 21, silicon nitride film 17B is deposited on the structure shown in FIG. 20, and interlayer insulating film 15C is deposited on silicon nitride film 17B. Subsequently, a surface of interlayer insulating film 15C is flattened by CMP. Thereafter, holes for contact plug are formed in interlayer insulating film 15C on the first interconnect layers M1A and M1B, respectively, by a lithography method and RIE. Furthermore, an interconnect trench to arrange a second interconnect layer is formed in interlayer insulating film 15C on the hole for contact plug by a lithography method and RIE. Subsequently, a barrier metal and a Cu seed layer are formed in the holes for contact plug and the interconnect trench by a sputtering method. Furthermore, Cu plating is formed on the Cu seed layer. Excessive Cu on interlayer insulating film 15C is polished by CMP, as shown in FIG. 21, to form contact plugs 20A and 20C and the second interconnect layers M2A and M2B each having a damascene structure. Furthermore, silicon nitride film 17C is deposited on the second interconnect layers M2A and M2B and interlayer insulating film 15C.

As shown in FIG. 17, interlayer insulating film 15D is deposited on silicon nitride film 17C. Subsequently, a surface of interlayer insulating film 15D is flattened by CMP. Thereafter, holes for contact plug are formed in interlayer insulating film 15D on the second interconnect layers M2A and M2B and the intermediate plug 21 by a lithography method and RIE. Furthermore, an interconnect trench to arrange a third interconnect layer is formed in interlayer insulating film 15C on the hole for contact plug by a lithography method and RIE. Subsequently, a barrier metal and a Cu seed layer are formed in the holes for contact plug and the interconnect trench by a sputtering method. Furthermore, Cu plating is formed on the Cu seed layer. Excessive Cu on interlayer insulating film 15D is polished by CMP, as shown in FIG. 17, to form contact plugs 23A, 23B, and 23C and the third interconnect layers M3A and M3B each having a damascene structure. Furthermore, silicon nitride film 17D is deposited on the third interconnect layers M3A and M3B and interlayer insulating film 15D. In this manner, a semiconductor memory device in which an MRAM and a logic circuit are embedded is formed.

In the fourth embodiment, the MTJ element 19 is formed in a layer at the same level as that of contact plug 20A in an MRAM region to make a contact plug under the first interconnect layer in a logic circuit region unnecessary. The other configurations and effects are the same as those in the first embodiment.

### Fifth Embodiment

A semiconductor memory device according to a fifth embodiment of the present invention will be described below. The same reference numbers as in the configuration in the first embodiment denote the same parts in the fifth embodiment.

In the first embodiment and the second embodiment, it is observed that the MTJ element and the intermediate plug tend to be excessively etched by a smoothing process for the first interconnect layers M1A and M1B. In the fifth embodiment, a film thickness of the first interconnect layer M1A in an MRAM region is set to be larger than that of the first interconnect layer M1B in a logic circuit region to solve the problem.

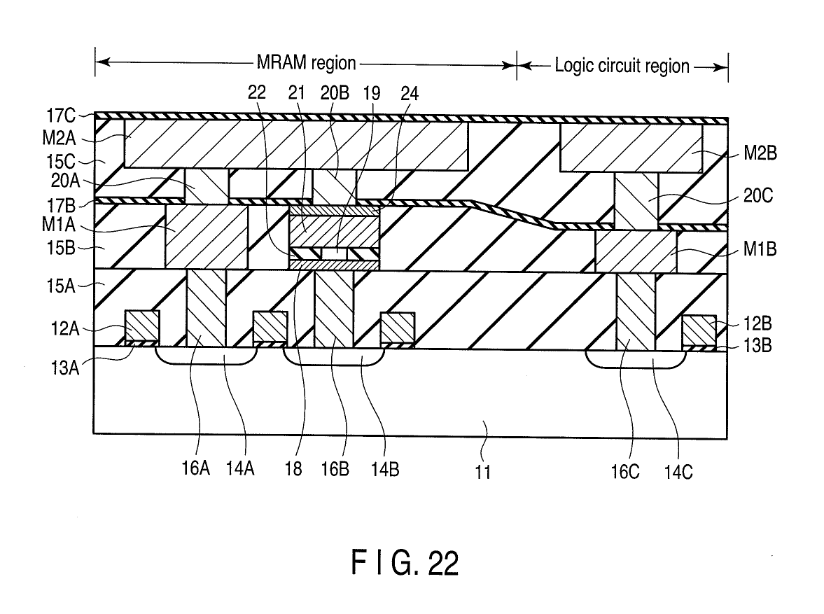

FIG. 22 is a sectional view showing a structure of the semiconductor memory device according to the fifth embodiment.

A structure of the MRAM region is as follows. As in the first embodiment, a MOS transistor is formed on the semiconductor substrate 11. Interlayer insulating film 15A is formed on the semiconductor substrate 11. On diffusion layer 14A of the MOS transistor, contact plug 16A is formed to be in contact with diffusion layer 14A. Furthermore, on diffusion layer 14B, contact plug 16B is formed to be in contact with diffusion layer 14B.

Interlayer insulating film 15B is formed on interlayer insulating film 15A. In interlayer insulating film 15B on contact plug 16A, the first interconnect layer M1A is formed to be in contact with contact plug 16A. In interlayer insulating film 15B on contact plug 16B, the lower electrode 18 is formed, and the MTJ element 19 is formed on the conductive film 18. The intermediate plug 21 is formed on the MTJ element 19, and a silicon nitride film 24 is formed on the intermediate plug 21. Furthermore, the interlayer insulating film 22 is formed between the lower electrode 18 and the intermediate plug 21.

Silicon nitride film 17B is formed on the first interconnect layer M1A, the silicon nitride film 24, and interlayer insulating film 15B, and interlayer insulating film 15C is formed on silicon nitride film 17B.

In interlayer insulating film 15C on the first interconnect layer M1A, contact plug 20A is formed to be in contact with the first interconnect layer M1A. In interlayer insulating film 15C on the silicon nitride film 24, contact plug 20B is formed to be in contact with the silicon nitride film 24. In interlayer insulating film 15C on contact plugs 20A and 20B, the second interconnect layer M2A is formed to be in contact with contact plugs 20A and 20B. Furthermore, silicon nitride film 17C is formed on the second interconnect layer M2A and interlayer insulating film 15C.

A structure of the logic circuit region is as follows. As in the first embodiment, a MOS transistor is formed on the semiconductor substrate 11. Interlayer insulating film 15A is formed on the semiconductor substrate 11. In interlayer insulating film 15A on diffusion layer 14C of the MOS transistor, contact plug 16C is formed to be in contact with diffusion layer 14C.

Interlayer insulating film 15B is formed on interlayer insulating film 15A. In interlayer insulating film 15B on contact plug 16C, the first interconnect layer M1B is formed to be in contact with contact plug 16C.

Silicon nitride film 17B is formed on interlayer insulating film 15B and the first interconnect layer M1B, and interlayer insulating film 15C is formed on silicon nitride film 17B. In interlayer insulating film 15C on the first interconnect layer M1B, contact plug 20C is formed to be in contact with the first interconnect layer M1B. In interlayer insulating film 15C on contact plug 20C, the second interconnect layer M2B is formed to be in contact with contact plug 20C. Furthermore, silicon nitride film 17C is formed on the second interconnect layer M2B and interlayer insulating film 15C.

A method of manufacturing a semiconductor memory device according to the fifth embodiment will be described below.

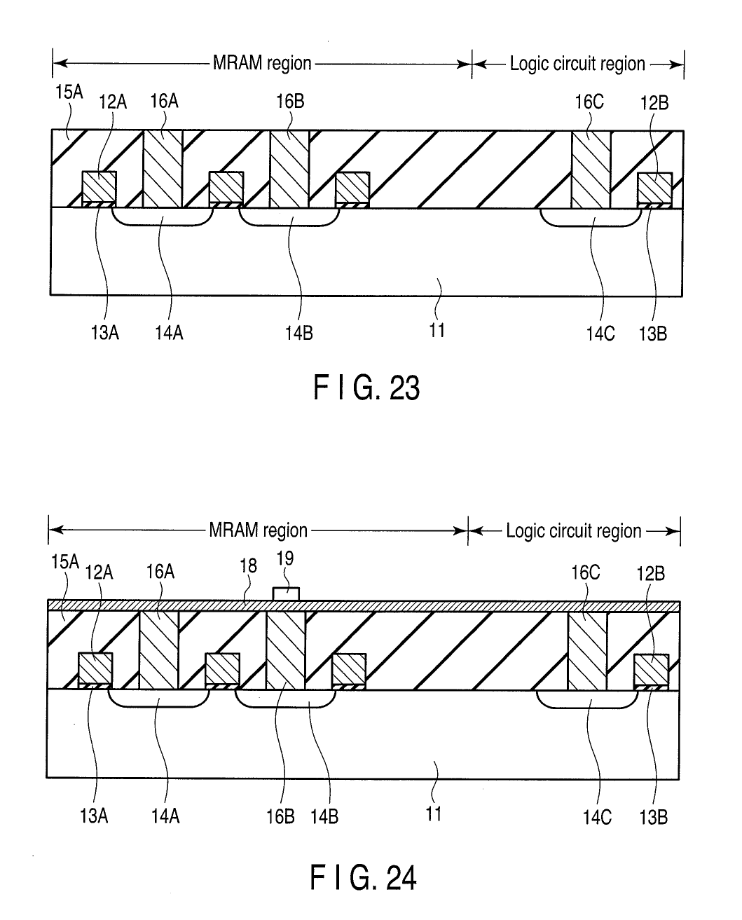

FIGS. 23 to 27 are sectional views showing the method of manufacturing a semiconductor memory device according to the fifth embodiment.

As shown in FIG. 23, in an MRAM region and a logic circuit region, a MOS transistor is formed on the semiconductor substrate 11. Subsequently, interlayer insulating film 15A is formed on the semiconductor substrate 11 on which a MOSFET is formed. Furthermore, on diffusion layers 14A, 14B, and 14C, contact plugs 16A, 16B, and 16C are formed, respectively. The above steps are the same as those shown in FIG. 2.

As shown in FIG. 24, on interlayer insulating film 15A on which a contact plug is formed, the conductive film 18 serving as a lower electrode is deposited. Subsequently, a film serving as an MTJ element is formed on the conductive film 18. The film serving as the MTJ element is patterned by a lithography method and RIE to form the MTJ element 19 on the conductive film 18 on contact plug 16B.

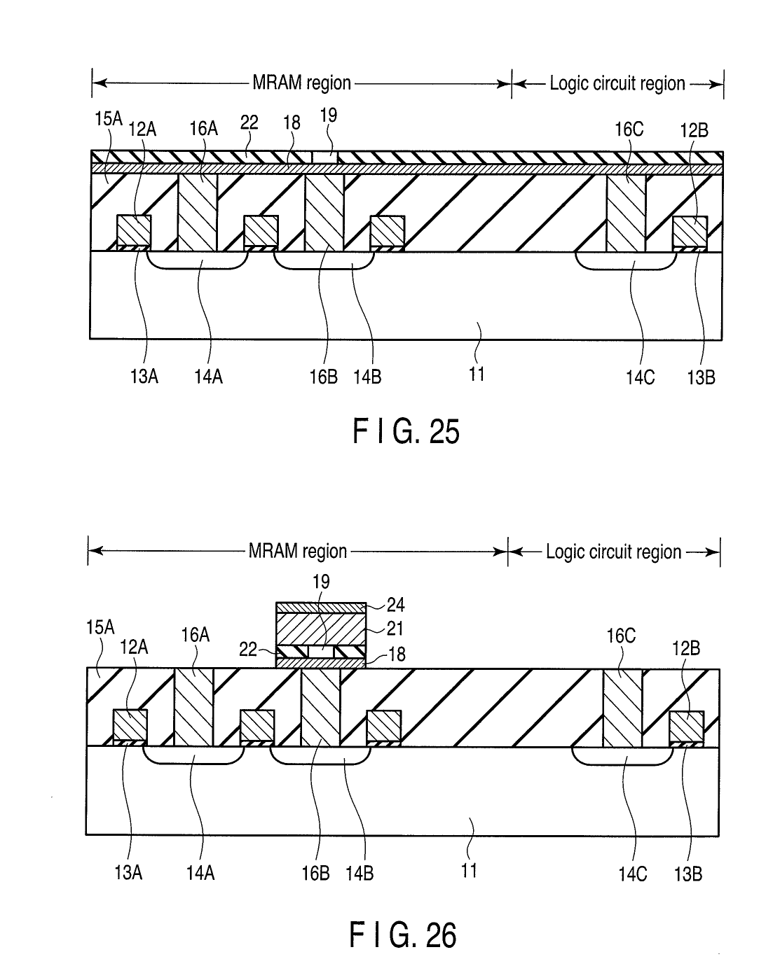

As shown in FIG. 25, the interlayer insulating film 22 is deposited on the structure shown in FIG. 24. Subsequently, a surface of the interlayer insulating film 22 is flattened by CMP to expose a surface of the MTJ element 19.

Thereafter, a film 21 (for example, a TiN film) serving as an intermediate plug is deposited on the interlayer insulating film 22 and the MTJ element 19. Furthermore, the silicon nitride film 24 is deposited on the film 21 serving as the intermediate plug. The silicon nitride film 24, the film 21 serving as the intermediate plug, the interlayer insulating film 22, and the conductive film 18 are patterned by a lithography method and RIE, as shown in FIG. 26, to form the intermediate plug 21 and the silicon nitride film 24 on the MTJ element 19 and to form the lower electrode 18 on contact plug 16B.

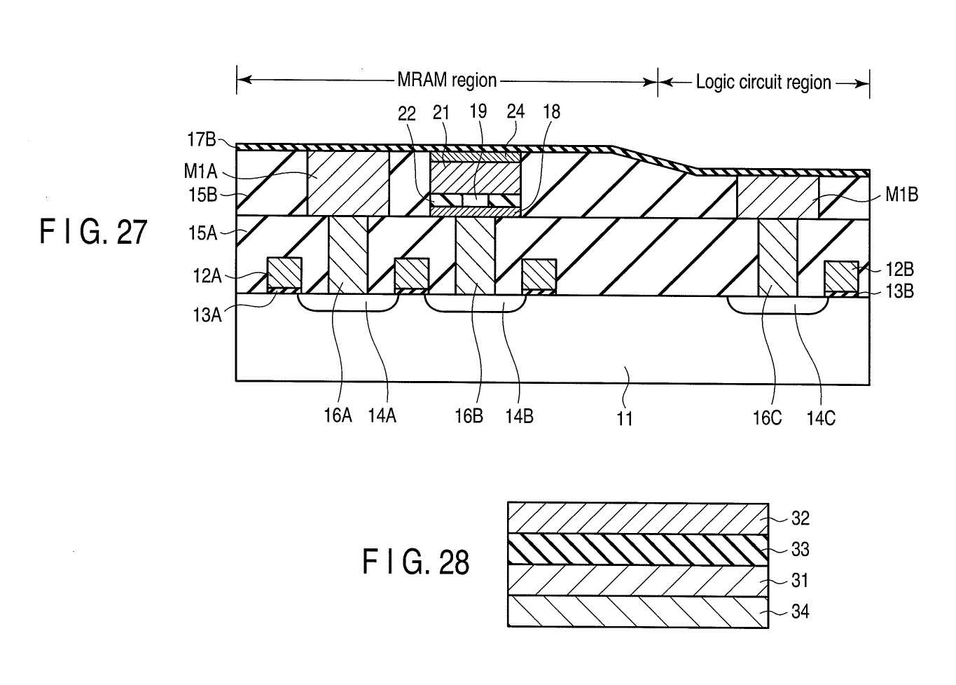

As shown in FIG. 27, interlayer insulating film (for example, a silicon oxide film) 15B is deposited on the structure shown in FIG. 26. Thereafter, a surface of interlayer insulating film 15B is flattened by CMP. At this time, the silicon nitride film 24 on the intermediate plug 21 is used as a stopper for a polishing step performed by CMP.

An interconnect trench to arrange a first interconnect layer is formed in interlayer insulating film 15B on contact plugs 16A and 16C by a lithography method and RIE. Subsequently, a barrier metal and a Cu seed layer are formed in the interconnect trench by a sputtering method. Furthermore, Cu plating is formed on the Cu seed layer. Excessive Cu on interlayer insulating film 15B is polished by CMP, as shown in FIG. 27, to form the first interconnect layers M1A and M1B each having a damascene structure in interlayer insulating film 15B. At this time, the first interconnect layer M1B in the logic circuit region is polished by CMP to have a predetermined film thickness. Furthermore, silicon nitride film 17B is deposited on the first interconnect layers M1A and M1B, the silicon nitride film 24, and interlayer insulating film 15B.

Interlayer insulating film 15C is formed on the structure shown in FIG. 27. Subsequently, holes for contact plug are formed in interlayer insulating film 15C on the first interconnect layers M1A and M1B and the silicon nitride film 24 by a lithography method and RIE. Furthermore, an interconnect trench to arrange a second interconnect layer is formed in interlayer insulating film 15C on the holes for contact plug by a lithography method and RIE. Subsequently, a barrier metal and a Cu seed layer are formed in the holes for contact plug and the interconnect trench by a sputtering method. Furthermore, Cu plating is formed on the Cu seed layer. Excessive Cu on interlayer insulating film 15C is polished by CMP, as shown in FIG. 22, to form contact plugs 20A, 20B, and 20C and the second interconnect layers M2A and M2B each having a dual damascene structure. Furthermore, silicon nitride film 17C is deposited on the second interconnect layers M2A and M2B and interlayer insulating film 15C. In this manner, a semiconductor memory device in which an MRAM and a logic circuit are embedded is manufactured.

In the fifth embodiment, a film thickness of the first interconnect layer M1A in the MRAM region is set to be larger than that of the first interconnect layer M1B in the logic circuit region to make it possible to prevent the MTJ element 19 or the intermediate plug 21 from being etched in a smoothing process for the first interconnect layers M1A and M1B. The other configurations and effects are the same as those in the first embodiment.

Finally, an MTJ element serving as a magnetoresistive effect element included in the semiconductor memory device according to the first to fifth embodiments will be described below.

FIG. 28 is a sectional view showing a structure of the MTJ element included in the semiconductor memory device according to the embodiment. As shown in the drawing, an insulating layer (tunnel barrier layer) 33 is arranged between two magnetic layers (ferromagnetic layers) 31 and 32. Furthermore, an antiferromagnetic layer 34 is arranged on a surface opposing a surface on which the tunnel barrier layer of one magnetic layer 31 is arranged. The magnetic layer 31 on a side on which the antiferromagnetic layer 34 is arranged is called a reference layer (fixed layer). The antiferromagnetic layer 34 is a member to fix a direction of spin of the magnetic layer 31 on one side. A direction of spin of the magnetic layer 32 (recording layer) on the other side is changed to rewrite information stored in the MTJ element.

According to the embodiments of the present invention, a semiconductor memory device which can be operated at high speed and which includes a logic circuit and an MRAM can be provided.

The embodiments described above can not only be singularly executed but also be executed in combination with each other. Furthermore, the embodiments described above include inventions in various phases. A plurality of constituent elements disclosed in the embodiments are arbitrarily combined to each other to make it possible to extract the inventions in the various phases.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a first MOS transistor on a semiconductor substrate;
an interlayer insulating film on the first MOS transistor;
a first contact plug and a second contact plug in the interlayer insulating film, the first contact plug being on either a source region or a drain region of the first MOS transistor, and the second contact plug being on either the drain region or the source region, respectively;
a first interconnect layer on the first contact plug;
a magnetoresistive effect element on the second contact plug, the magnetoresistive effect element being in a layer comprising a height substantially equal to a height of the first interconnect layer from a semiconductor substrate surface;
a second MOS transistor on the semiconductor substrate;
a third contact plug in the interlayer insulating film on one of a source region and a drain region of the second MOS transistor; and
a second interconnect layer on the third contact plug, the second interconnect layer being in a layer comprising a height substantially equal to heights of the first interconnect layer and the magnetoresistive effect element from the semiconductor substrate surface.

2. The semiconductor memory device of claim 1,
further comprising a lower electrode between the second contact plug and the magnetoresistive effect element, the lower electrode being in a layer having a height substantially equal to the height of the first interconnect layer from the semiconductor substrate surface.

3. The semiconductor memory device of claim 1,
further comprising an intermediate plug on the magnetoresistive effect element, the intermediate plug being in a layer comprising a height substantially equal to the height of the first interconnect layer from the semiconductor substrate surface.

4. The semiconductor memory device of claim 1,
wherein a thickness of the first interconnect layer is larger than a thickness of the second interconnect layer, a bottom surface of the first interconnect layer from the semiconductor substrate surface and a bottom surface of the second interconnect layer from the semiconductor substrate surface comprise the same height, and an upper surface of the first interconnect layer from the semiconductor substrate surface is higher than an upper surface of the second interconnect layer from the semiconductor substrate surface.

5. The semiconductor memory device of claim 4, further comprising:
a lower electrode between the second contact plug and the magnetoresistive effect element, the lower electrode being in a layer comprising a height substantially equal to the height of the first interconnect layer from the semiconductor substrate surface;
an intermediate plug on the magnetoresistive effect element, the intermediate plug being in a layer comprising a height substantially equal to the height of the first interconnect layer from the semiconductor substrate surface; and
a silicon nitride film on the intermediate plug, an upper surface of the silicon nitride film comprising a height substantially equal to a height of an upper surface of the first interconnect layer from the semiconductor substrate surface.

6. The semiconductor memory device of claim 1,
wherein the first interconnect layer is in contact with the first contact plug, and the second interconnect layer is in contact with the third contact plug.

7. The semiconductor memory device of claim 1,
further comprising a silicon nitride film on the interlayer insulating film.

8. A semiconductor memory device comprising:
a first MOS transistor on a semiconductor substrate;
an interlayer insulating film on the first MOS transistor;
a first contact plug and a second contact plug in the interlayer insulating film, the first contact plug being on either a source region or a drain region of the first MOS transistor, and the second contact plug being on either the drain region or the source region, respectively;
a first interconnect layer on the first contact plug;
a magnetoresistive effect element on the second contact plug, the magnetoresistive effect element being in a layer comprising a height substantially equal to a height of the first interconnect layer from a semiconductor substrate surface;
a second MOS transistor on the semiconductor substrate;
a third contact plug in the interlayer insulating film on one of a source region and a drain region of the second MOS transistor; and
a second interconnect layer on the third contact plug, a bottom surface of the second interconnect layer being at a position higher than a bottom surface of the first interconnect layer from the semiconductor substrate surface.

9. The semiconductor memory device of claim 8,
further comprising a lower electrode between the second contact plug and the magnetoresistive effect element, the lower electrode being in a layer having a height substantially equal to the height of the first interconnect layer from the semiconductor substrate surface.

10. The semiconductor memory device of claim 8,
wherein a thickness of the first interconnect layer is larger than a thickness of the second interconnect layer, and an upper surface of the first interconnect layer from the semiconductor substrate surface and an upper surface of the second interconnect layer from the semiconductor substrate surface comprise the same height.

11. The semiconductor memory device of claims 8,
wherein the first interconnect layer is in contact with the first contact plug, and the second interconnect layer is in contact with the third conduct plug.

12. The semiconductor memory device of claim 8,
further comprising a silicon nitride film on the interlayer insulating film.

13. A semiconductor memory device comprising:
a first MOS transistor on a semiconductor substrate;
a first interlayer insulating film on the first MOS transistor;
a first contact plug and a second contact plug in the first interlayer insulating film, the first contact plug being on either a source region or a drain region of the first MOS transistor, and the second contact plug being on either the drain region or the source region, respectively;
a first interconnect layer on the first contact plug;
a second interconnect layer on the second contact plug, the second interconnect layer being in a layer comprising a height substantially equal to that of the first interconnect layer from a semiconductor substrate surface;
a second interlayer insulating film on the first interlayer insulating film;
a third interconnect layer in the second interlayer insulating film on the first interconnect layer;
a magnetoresistive effect element in the second interlayer insulating film on the second interconnect layer;
a second MOS transistor on the semiconductor substrate;
a third contact plug in the first interlayer insulating film on one of a source region and a drain region of the second MOS transistor; and
a fourth interconnect layer on the third contact plug, the fourth interconnect layer being in a layer having a height substantially equal to heights of the first interconnect layer and the second interconnect layer from the semiconductor substrate surface.

14. The semiconductor memory device of claim 13,
further comprising a lower electrode between the second interconnect layer and the magnetoresistive effect element.

15. The semiconductor memory device of claim 13,
further comprising an intermediate plug on the magnetoresistive effect element, the intermediate plug being in the second interlayer insulating film.

16. The semiconductor memory device of claim 13,
wherein the first interconnect layer is in contact with the first contact plug, the second interconnect layer is in contact with the second contact plug, and the fourth interconnect layer is in contact with the third contact plug.
